(19) United States
(12) Patent Application Publication
(10) Pub. No.: US 2026/0210281 A1
(43) Pub. Date: Jul. 23, 2026

(54) SYSTEMS AND METHODS FOR ADAPTIVE ENTHALPY DISTRIBUTION MANAGEMENT

(71) Applicant: Daimler Truck North America LLC, Portland, OR (US)

(72) Inventors: Daniel BULLMORE, Portland, OR (US); Rasik PONDICHERRY, Detroit, MI (US); Alexander ALFERY, Detroit, MI (US)

(73) Assignee: Daimler Truck North America LLC, Portland, OR (US)

(21) Appl. No.: 19/139,762

(22) PCT Filed: Nov. 17, 2023
(86) PCT No.: PCT/US2023/080318

§ 371 Date: Jun. 16, 2025

Related U.S. Application Data
(60) Provisional application No. 63/387,572, filed on Dec. 15, 2022.

(51) Int. Cl. F01P 3/20; B60L 58/26; F01P 7/14; G06F 30/15; H01M 8/04992; H01M 16/00

(52) U.S. Cl. CPC F01P 3/20; B60L 58/26; F01P 7/14; G06F 30/15; H01M 8/04992; H01M 16/006; F01P 2007/146; H01M 2220/20; H01M 2250/20; H01M 2250/402

(57) ABSTRACT

Systems and methods for efficient, adaptive, and dynamic enthalpy distribution management are provided. In one aspect, an enthalpy management controller that operates in conjunction with a thermal transfer system to distribute heat between system components based on component enthalpy models is provided. The controller may monitor enthalpy models for a plurality of components coupled to a thermal transfer system, to assess whether a component is operating within a target operating enthalpy band. Based on the assessment, and similar assessments for the other components coupled to the thermal transfer system, the controller may control the thermal transfer system to transfer heat between the plurality of components, for example, to attempt to bring one or more components into operation within their respective operating enthalpy bands. When the enthalpy response of a component deviates from a response predicted, adjustments may be made to the component enthalpy model to adjust the component enthalpy model.

### CROSS-REFERENCE TO RELATED APPLICATIONS

This application is a PCT International Patent Application claiming priority to, and the benefit of, U.S. Provisional Patent Application No. 63/387,572, titled “SYSTEMS AND METHODS FOR ADAPTIVE ENTHALPY DISTRIBUTION MANAGEMENT”, filed on Dec. 15, 2022, which is incorporated herein by reference in its entirety. This application is related to U.S. Provisional Patent Application No. 63/514,321, titled “THERMAL MANAGEMENT COMPONENT, SYSTEM, AND METHOD OF MANUFACTURING AND USING THE SAME”, filed on Jul. 18, 2023, which is incorporated herein by reference in its entirety.

### BACKGROUND

Vehicles that use an internal combustion engine typically generate surplus heat during their operation that must be dissipated into the external environment in order to avoid overheating scenarios that can lead to reduced performance, damage, or loss of engine operation. One solution for cooling internal combustion engines is a closed-loop coolant-filled heat exchanger system that receives heat from the engine and transfers that heat to a liquid coolant that is then transferred to a radiator where the heat in the liquid coolant can then be transferred to an external environment. This typically provides adequate thermal management for internal combustion engines because internal combustion engines typically produce heat in surplus during operation, and with temperatures high enough to allow the heat to be readily transferred to the external environment. However, in certain vehicle thermal management scenarios, e.g., those occurring in connection with the operation of vehicles driven by internal combustion and/or by electric power, this traditional management of thermal energy can be limited in efficiency, adaptability, and capability, among other issues. Moreover, traditional thermal management technologies do not adequately address battery powered electric vehicles where vehicle range and/or battery performance, for example, may be adversely be affected by both excess heat and conditions where there is insufficient heat.

### SUMMARY

This summary is intended to introduce a selection of concepts in a simplified form that are further described below in the detailed description section of this disclosure. This summary is not intended to identify key or essential features of the claimed subject matter, nor is it intended to be used as an aid in isolation to determine the scope of the claimed subject matter.

In brief, and at a high level, this disclosure describes systems, methods, and technologies for adaptive enthalpy distribution management. This adaptive enthalpy distribution management can be applied to different systems and/or sub-systems whose components generate, store, and/or consume or require thermal energy as part of their operation. For example, these systems and sub-systems can be those associated with vehicles, aircraft, trains, ships, industrial equipment, and/or power generation equipment, among other things. In different embodiments, the systems, methods, and technologies described herein can determine the amount of thermal energy associated with different components of a system, determine energy needs of the components, e.g., determine if there is a need for a temperature increase, a temperature decrease, or continued operation in a current temperature band (e.g., based on each components'specifications and/or based on a thermal model), and then determine if surplus energy associated with one component can be transferred to another component within the system to accommodate the energy needs, while considering the energy lost from the component from which energy is obtained. This operation can allow for efficient, adaptive, and dynamic transfer of thermal energy within a system or sub-system, allowing for continued balancing of thermal energy while limiting the energy needed to generate additional heating and thus increasing efficiency in energy use and management, among other benefits.

The embodiments described herein that enable adaptive enthalpy distribution management are discussed frequently in connection with vehicles but are not limited to such applications. To describe one example use of adaptive enthalpy distribution management, a vehicle enthalpy management environment will be described. Traditional vehicles that use an internal combustion engine typically generate surplus heat. Thermal management systems for vehicles that use an internal combustion engine therefore primarily operate to keep temperatures within operating parameters by controlling, and facilitating, the dissipation of excess heat to the outside environment as needed. Thermal management in an electric vehicle can also require optimally distributing and/or storing the relatively limited amount of heat produced by the operation of the different components and systems of the electric vehicle, e.g., electric motors, batteries, regenerative braking systems, electronics, and the like. To optimally distribute and/or manage thermal energy in these environments, an enthalpy management controller can be used. The enthalpy management controller can operate in conjunction with a thermal transfer system to intelligently, adaptively, and/or dynamically distribute (e.g., transfer) heat between different components of a system based on component enthalpy models for that system and/or components thereof. As the term is used herein, a component enthalpy model is a mathematical model that computes an expected enthalpy (e.g., heat load) of a physical element (e.g., an object, an electrical and/or mechanical component, a fluid) given one or more observable, or computable, physical parameters of, and/or interacting with, the physical object. In some embodiments, a component enthalpy model may further quantify deviations between the enthalpy of the component and desired thermal specification for that component. As further discussed herein, in some embodiments, the component enthalpy models may be described as being “adaptive” component enthalpy models because the models themselves may be dynamically adjusted when it is determined that predicted enthalpy estimates no longer accurately reflect actual enthalpy within established thresholds.

In some instances, the enthalpy management controller may monitor component enthalpy models for each of a plurality of components coupled to a thermal transfer system, to assess whether a component is operating above, below, or within an operating enthalpy band (e.g., which may be computed from an operating temperature range pre-defined or pre-determined based on a component's specifications). Based on that assessment, and similar assessments for the other components coupled to the thermal transfer system, the enthalpy management controller can selectively transfer heat between the plurality of components, e.g., to attempt to bring one or more components to a temperature or temperature range that corresponds to the components'operating enthalpy band(s). In some embodiments, the enthalpy management controller may apply one or more criteria to determine when to utilize auxiliary thermal management components, such as traditional heaters, coolers, and the like, either in conjunction with, or instead of, the thermal transfer system. That is, the enthalpy management controller may apply logic to select between leveraging thermal energy transfer between the component(s) and the use-of auxiliary components to meet the respective component thermal operating targets.

In additional embodiments, when the enthalpy management controller makes adjustments to the thermal transfer system, e.g., initiating a transfer of thermal energy from one component to another, and the enthalpy response of a component deviates from the response predicted, one or more adjustments can be made to the component enthalpy model to compensate for inaccuracies, changes, or updates to the enthalpy state variables used by the component enthalpy model. The adjustments to the component enthalpy model may trigger alerts and/or other communications, and/or may be communicated to another computing device and/or system, e.g., one that is local and/or remote, so that the computing device or system can adjust accordingly. In another embodiment, adjustments being needed or made to one or more component enthalpy models can result in a vehicle being scheduled for service, e.g., for assessment, repair, and/or as part of a preventive maintenance program, among other things.

### BRIEF DESCRIPTION OF THE DRAWINGS

The embodiments presented in this disclosure related to systems, methods, and technologies for enthalpy distribution management are described in detail below with reference to the attached drawing figures, which illustrate non-limiting examples of the disclosed subject matter, wherein:

FIG. 1 is a block diagram illustrating a thermal management system, in accordance with embodiments of the present disclosure;

FIG. 2 is a block diagram illustrating an enthalpy management controller, in accordance with embodiments of the present disclosure;

FIG. 3 is a diagram illustrating a graphical representation of a component enthalpy model, in accordance with embodiments of the present disclosure;

FIG. 4 is a block diagram illustrating enthalpy model metrics, in accordance with embodiments of the present disclosure;

FIG. 5 is a flow chart illustrating an example method of enthalpy distribution management, in accordance with embodiments of the present disclosure;

FIG. 6 is a diagram illustrating an example computing environment suitable for supporting the operations and functions described herein, in accordance with embodiments of the present disclosure; and

FIG. 7 is a diagram illustrating an example cloud-based computing environment, in accordance with embodiments of the present disclosure.

### DETAILED DESCRIPTION

This detailed description is provided in order to meet statutory requirements. However, this description is not intended to limit the scope of the embodiments described herein. Rather, the claimed subject matter may be embodied in different ways, to include different steps, combinations of steps, different elements, and/or different combinations of elements, similar to those described herein, and in conjunction with other present or future technologies. Moreover, although the terms “step” and “block” may be used herein to identify different elements of methods employed, the terms should not be interpreted as implying any particular order among or between different elements except when the order is explicitly described.

In general, this disclosure is directed to systems, methods, and technologies that enable efficient, adaptable, and dynamic enthalpy distribution management across different mechanical and/or electrical systems and/or sub-systems, e.g., those associated with vehicles, aircraft, trains, ships, industrial equipment, power-generation equipment, or with other operating environments, among other things. In an example, the embodiments described herein can be used with vehicles powered by internal combustion, e.g., gasoline or diesel-powered engines, and/or can be used with vehicles that are electrically-powered, e.g., those that are battery electric, hybrid electric, plug-in-hybrid electric, fuel cell electric, or that otherwise obtain power and operation from electrical systems. In particular, the systems, methods, and technologies described herein can be used with cars, trucks, and/or other consumer or commercial vehicles, among other things.

Traditional vehicles that use an internal combustion engine typically generate surplus waste heat at different points during their operation. Even after heat generated by the engine is used to bring the engine, lubricants, fluids, batteries, the cabin environment and other auxiliary systems into their optimal operating temperate range, there typically can still be excess heat produced by the engine that needs to be dissipated to the external environment. Thermal management systems for internal combustion engine vehicles are therefore primarily designed to solve the problem of how to dissipate excess heat to the environment. This can be accomplished through use of a cooling system that includes, for example, a heat exchanger and a fan. Thermal management systems for an electric vehicle need to address the problem of how to optimally distribute and/or store the relatively limited amount of heat produced by the vehicle's components. To accomplish this, a system that allows for a more efficient, adaptable, and intelligent distribution of heat between vehicle components/systems, e.g., electric motors, brakes, axles, fluids, lubricants, batteries, a cabin environment, and/or other components/systems, to thereby allow those components/systems to reach and maintain a target temperature in their operating temperature range, while limiting the amount of energy wasted, e.g., dissipated to the environment, or used to generate heat for components not within their operating temperature range when heat is otherwise available for transfer, is provided herein. In other words, a system that intelligently uses available thermal energy for best use, and least waste, is provided by the embodiments discussed in this disclosure.

In one embodiment, an enthalpy management controller that operates in conjunction with a thermal transfer system to intelligently distribute (e.g., transfer, re-balance, or shift) thermal energy between different system components, e.g., in response to temperature indications, and/or based at least in part on adaptive component enthalpy models, is provided. For example, in one embodiment, the system components can be vehicle components. As the term is used herein, enthalpy refers to a thermodynamic quantity equivalent to the total heat content of a component and/or system. Vehicle components that may generate heat during normal operation may include, but are not limited to, braking system equipment and transmission systems (e.g., that can generate heat through friction between components), electric motors (e.g., that can generate heat from transfer of electrical current through coil windings), and/or electrical circuits (e.g., amplifiers and processing electronics that generate heat through transfer of electrical current through the electrical circuits). Vehicle components that may not generate heat (in substantial quantity) during normal operation, but may need to maintain their temperature within a specified range for proper operation, may include, but not are limited to, components such as hydraulic systems, lubricating systems, batteries, valves, actuators, fluid supply lines, and/or cabin environmental systems, among other things.

In some embodiments, an enthalpy management controller may monitor component enthalpy models for each of a plurality of components coupled to a thermal transfer system, to assess whether a component is operating above, below, or within an operating enthalpy band. As the term is used herein, an operating enthalpy band for a component refers to an enthalpy range considered (for example, by the component manufacturer or designer) to be normal or optimal for nominal operation under an expected range of operating conditions. In some embodiments, an operating enthalpy band for a component may be specified by a manufacturer's data sheet for the component. In some embodiments, the operating enthalpy band may be computed from pre-defined or pre-set component specifications. For example, an operating enthalpy band may be computed from manufacturer-designated temperature ranges specified as optimal for component operation. As the term is used herein, a component enthalpy model is a mathematical model that computes an expected enthalpy (e.g., heat load) of a physical element (e.g., an object, a component, a fluid) given one or more observable, or computable, physical parameters of, and/or interacting with, the physical object. For example, in some embodiments, a heat load of a basic fluid system may be computed as a function of parameters such as mass flow rate, specific heat, and change in temperature. That said, component enthalpy models for modeling the enthalpy of components described herein may include, but are not limited to, linear or non-linear formulas, iterative and/or recursive algorithms, machine learning algorithms, rules based policies, or other forms of logic, for example. As further discussed herein, in some embodiments, the component enthalpy models may be described as being “adaptive” component enthalpy models because the models themselves may be dynamically adjusted when it is determined that predicted enthalpy estimates are no longer accurately reflecting actual enthalpy within established thresholds.

Based on the assessment of that component by the enthalpy management controller, and similar assessments for the other components coupled to a thermal transfer system, the enthalpy management controller may control the thermal transfer system to transfer thermal energy or heat between different components as needed, e.g., in order to bring one or more components into operation within their respective operating enthalpy bands (e.g., operating temperature ranges). In some embodiments, by leveraging heat load models, the enthalpy management controller may identify components having a capacity to store thermal energy (e.g., such as batteries that have substantial thermal mass) so that excess heat generated by other components can be transferred to those components with such thermal storage capacity, for potential later use. In some embodiments, when a heat transfer may not be efficiently attained by the thermal transfer system, the enthalpy management controller may leverage the use of auxiliary components in the system (such as heaters and/or coolers, for example) as an attempt to meet the desired operational limits/thresholds. For example, in some embodiments when a component enthalpy model for a component continues to trend away from a target enthalpy and or out of its respective operating enthalpy band, the enthalpy management controller may determine to utilize auxiliary components in addition to, or together with, the thermal transfer system. Similarly, in some embodiments, the enthalpy management controller may determine that other components managed by the thermal transfer system may not have sufficient margin to share and/or accept heat to bring a component's enthalpy model to its target enthalpy, and based on that determination decides to utilize auxiliary components in addition to, or together with, the thermal transfer system in order to manage heat exchange sufficiently.

In accordance with aspects herein, for each of the connected components of a system, sensor data indicating one or more parameters of the component can be monitored (e.g., obtained from either sensor measurements or computed estimates) and used as inputs to an adaptive component enthalpy model associated with the component. From the sensor data, the adaptive component enthalpy model can compute an output that includes an estimate of heat load (e.g., enthalpy measured in joules) and/or a rate of change of heat load (e.g., joules/sec) for that component. In some embodiments, a component enthalpy model may further quantify deviations between the enthalpy of the component and desired thermal specification for that component. These measurements and values, and/or other values, can be used to compute enthalpy state variables for that component that include an enthalpy state variable corresponding to the quantity of enthalpy stored in the component, and/or an enthalpy state variable corresponding the rate of change in the quantity of enthalpy stored in the component. In some embodiments, enthalpy models may be implemented as a pre-rendered matrix loaded into the enthalpy management controller. The estimated heat load and/or rate of change of heat load values may be output by the adaptive component enthalpy model in the form of a component enthalpy state vector descriptive of the current thermal state of that respective component. This process can be performed by a computer processor, e.g., one associated with an enthalpy management controller.

In some embodiments, the enthalpy management controller can receive the enthalpy state variables from each of the adaptive component enthalpy models and predict a future heat load for each of the plurality of components at a future point in time. Then, the enthalpy management controller can generate one or more control signals that are sent to the thermal transfer system to direct the flow of thermal energy between components to drive each component towards their respective operating enthalpy band (e.g., operating temperature range, heat load). To facilitate desired thermal balancing, the enthalpy management controller may direct the flow of thermal energy towards components that have available margin in their capacities to store thermal energy. If each component is within its respective operating enthalpy band and there is no capacity available for further thermal storage, the enthalpy management controller may generate a control signal to the thermal transfer system to direct thermal energy to a heat exchanger to shed part or all of the thermal energy to the external (ambient) environment. In some embodiments, the enthalpy management controller may direct the thermal transfer system to shed heat to the external environment in anticipation of a predicted increase in on-board generated enthalpy.

The enthalpy management controller may comprise a state prediction algorithm, such as a propagator-estimator, that generates a real time state observer using the outputs of the plurality of adaptive component enthalpy models associated with the plurality of components and/or inputs from real-time sensor data. For example, in some embodiments, a propagator-estimator (e.g., a Kalman filter and/or other linear quadratic estimation (LQE) algorithm) may include at least a state observer. The state observer may include a model that uses component enthalpy state variables (e.g., variables representing the enthalpy and/or a rate of change of enthalpy of a component) computed by each of the adaptive component enthalpy models as real time state measurements. Using a state predictor, the propagator-estimator produces statistically based estimates corresponding to a current set of estimated state variables (referred to as a state estimate) for a timestep, with their uncertainties, using a state estimate from the previous timestep. These state variables comprise representations of enthalpy (heat load) corresponding to each of the plurality of components. The differences between a currently predicted state estimate and the current observed measurement information from the state observer can be used to further refine the state estimate. This updated state estimate is then used in the next timestep as the prior state estimate (from the previous timestep) and the propagator-estimator iteratively converges on increasingly accurate estimates of enthalpy corresponding to each of the plurality of components.

In some embodiments, the enthalpy management controller comprises a system enthalpy control model that receives the state estimates of state variables from the propagator-estimator. The system enthalpy control model may include, for example, machine learning models, artificial intelligence, rules based policies, trim tables, crisp fuzzy logic (for example, where “crisp” as used in this context herein refers to the functional ability, e.g., triangular or trapezoidal abilities, to calibrate fuzzy logic mode switching), or other forms of logic, programed and/or trained to evaluate the state variables and control the thermal transfer system to adjust the heat load of each component, e.g., towards an operating range or threshold. For example, the system enthalpy control model may be programed with logic that can predict changes to a component's heat load in response to transferring a given amount of thermal energy either to or from the component, and evaluate where the resulting heat load is in comparison to that component's operating enthalpy band. In some embodiments, based on the computations performed by the system enthalpy control model, the enthalpy management controller may generate one or more control signals used to control the thermal transfer system to adjust the distribution of heat between the plurality of components to drive their heat loads based on their respective operating enthalpy bands. In some embodiments, the enthalpy management controller may utilize machine learning or other logic to create trim values to accommodate performance decline over time due to factor such as, but not limited to, component aging, degradation, fouling, or other factors. For example, in some embodiments, the enthalpy management controller may de-rate a component's thermal performance efficiency (e.g., using one or more trim values) over time as a function of e.g., time and/or mileage.

As previously mentioned, some of the embodiments described herein enable, at least in part, adaptive enthalpy distribution management within a system of distributed components through use of one or more adaptive component enthalpy model(s). For example, using a propagator-estimator to compute state estimates, the enthalpy management controller can account for errors in state estimates that can be considered expected errors (e.g., due to sensor inaccuracies, signal noise, measurement noise, random noise and/or fluctuations in signals and/or measured processes, and/or accumulations of small errors). Such random errors are often characterized as having predictable error distributions (e.g., such as a normal (Gaussian) error distribution). However, while the propagator-estimator attempts to minimize residual error in state estimates, continued error trends in state estimates corresponding to a component may indicate that the adaptive component enthalpy model for that component is no longer accurately translating sensor data to estimates of heat load and/or rate of change of heat load. That is, there may have been a change affecting the component itself such that the enthalpy response of the component from receiving or shedding thermal energy through the thermal transfer system is no longer accurately being modeled. For example, the fins of a radiator may become plugged with debris (e.g., from bugs or leaves) resulting in a reduced heat exchange efficiency. Similarly, other components may experience reduced heat exchange efficiencies due to leaks, blocked process flows, material accumulations on surfaces, or normal (and/or abnormal) component ware. Thus, there may be indications generated by the component enthalpy model that do not align directly with the actual enthalpy state.

When the enthalpy management controller makes adjustments to the thermal transfer system, but the enthalpy response of a component deviates from the response predicted by the state prediction algorithm (e.g., a deviation greater than a predetermined threshold), one or more adjustments may be made to the adaptive component enthalpy model. As a non-limiting example, in some embodiments, the adaptive component enthalpy model may use proportional-integral-derivative (PID) control algorithms to model component heat load characteristics. The enthalpy management controller may adjust one or more coefficients for the PID control algorithms based, for example, on whether the response predicted by the propagator-estimator was higher, lower, faster, slower, overdamped or underdamped, as compared to the observed response. In other embodiments, other control algorithms may be used by a component enthalpy model such as fuzzy logic controls and/or machine learning models, and the enthalpy management controller may adjust one or more coefficients of those control algorithms. In some embodiments, when cumulative adjustments to the adaptive component enthalpy model (e.g., as compared to a baseline) exceed one or more thresholds, the enthalpy management controller may generate an alert or warning signal (e.g., via an illuminated annunciator or alarm sound), log an event to table or ledger, set a flag, and/or transmit one or more signals to other vehicle systems or components. Adjustments to the adaptive component enthalpy model, and/or generated warnings, may be reported to a maintenance server or other system. Based on reports of adaptive component enthalpy model adjustments greater than a threshold value, a maintenance server may schedule a vehicle for service under a preventive maintained program to repair or adjust a component.

Advantageously, the embodiments for adaptive enthalpy distribution management described herein provide for intelligent control over how heat is distributed between components. Heat generated by components, e.g., vehicle components, can be managed as a resource to be intelligently shared, rather than as a harmful waste product to be shed. Moreover, by modeling component enthalpy rather than simply regulating based on temperature measurements, the embodiments presented herein more accurately account for an individual component's capacity to store thermal energy, receive thermal energy, donate thermal energy, respond to changes in thermal energy flow and capacity, in order to share thermal energy between components.

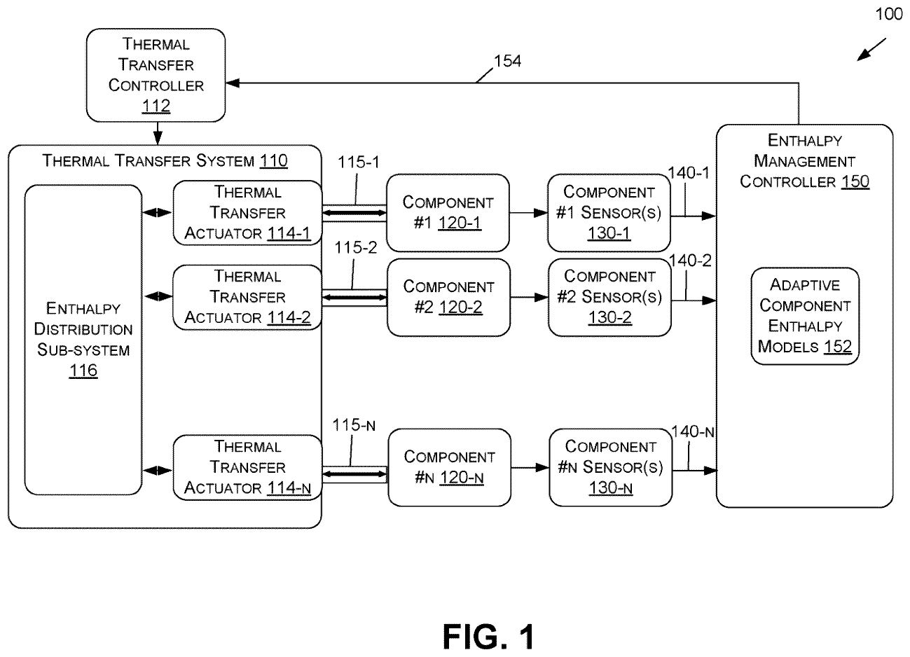

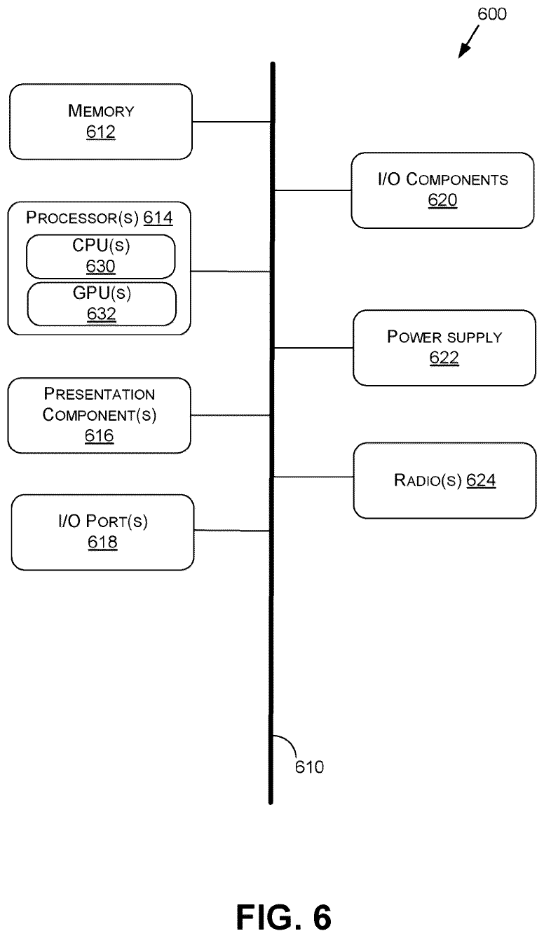

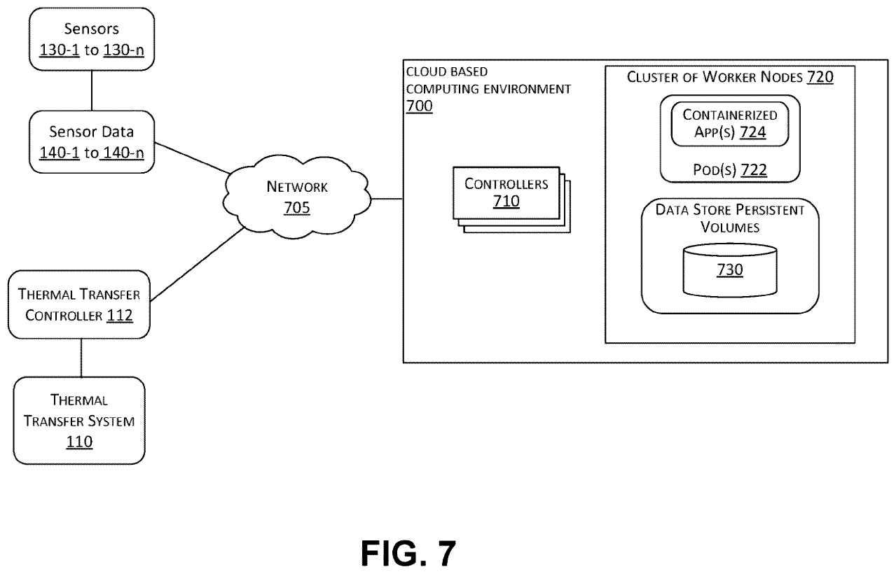

Referring now to FIG. 1, a diagram illustrating a thermal management system 100 for adaptive enthalpy distribution management in accordance with at least some embodiments of this disclosure is provided. Although one or more of the embodiments described herein present the thermal management system 100 in the context of a vehicle, such as an electric vehicle and/or battery electric vehicle, it should be understood that these embodiments may provide for thermal management in many different environments (e.g., automobiles, trucks, trains, aircraft, watercraft, spacecraft), machinery (e.g., robots and/or industrial machines), electronic systems, and/or other mobile or stationary systems having thermally-impacted components. Moreover, the thermal management system 100 described herein may be applied to systems that operate using any form of energy for power including internal combustion engines, gasoline-powered engines, diesel engines, fuel cells, batteries, solar energy, bio-fuels and/or other fuel/power source. One or more of the components shown in FIG. 1 can be implemented, at least in part, via any type of computing device, such as one or more of computing device 600 described in connection to FIG. 6, or at least in part within a cloud computing environment 700 as further described with respect to FIG. 7, for example. The thermal management system 100 may be considered a thermally dynamic system in that it comprises elements having thermal states that vary over time.

As illustrated in FIG. 1, the thermal management system 100 may include a thermal transfer system 110 that thermally couples a plurality of components (shown as components 120-1 to 120-n) to an enthalpy distribution sub-system 116. The components 120-1 to 120-n may comprise any component, for example, that either produces heat and/or is otherwise designed to optimally operate within specified temperature limits. Example components 120-1 to 120-n include, but are not limited to, braking system components, electric motor components, axles, fluid transfer components, lubrication systems, mechanical actuators, hydraulic components, electronic components, pumps, compressors, heat exchangers for vehicle cabin environment temperature regulation, and/or heat exchangers for shedding heat to the ambient environment. Each of the plurality of components 120-1 to 120-n may be coupled to the enthalpy distribution sub-system 116 via a respective thermal transfer link (shown as 115-1 to 115-n). Thermal transfer links may be implemented using any type of heat exchange device or material that channels thermal energy, such as but not limited to, conductive heat paths, convective and/or actively pumped closed loop fluid circulating systems, heat pipes, refrigeration systems (e.g., vapor compression, peltier, and the like) thermal phase change materials, and/or other components that may be used to direct thermal energy between the enthalpy distribution sub-system 116 and the plurality of components 120-1 to 120-n.

As shown in FIG. 1, heat transfer between the enthalpy distribution sub-system 116 and the plurality of components 120-1 to 120-n may be bi-directionally controlled using one or more thermal transfer actuators (shown as 114-1 to 114-n). That is, for example, at least one thermal transfer actuator (e.g., actuator 114-1) may be operated to cause the transfer of heat from the enthalpy distribution sub-system 116, through at least one thermal transfer link (e.g., thermal transfer line 115-1), into a corresponding component (e.g., component 120-1). Similarly, a thermal transfer actuator (e.g., actuator 114-1) may be operated to cause the transfer of heat from the corresponding component (e.g., component 120-1), through a thermal transfer link (e.g., thermal transfer line 115-1), into the enthalpy distribution sub-system 116. Heat transfer can thus be effectuated between components (e.g., between any of the components 120-1 to 120-n) by operating the corresponding thermal transfer actuators to create a thermal energy transfer path between the components through the enthalpy distribution sub-system 116. Each thermal transfer actuator may comprise any form of controllable heat flow control device such as, but not limited to valves, gates, switches, pneumatic devices, contacts and/or mechanical thermal junctions or interfaces. The enthalpy distribution sub-system 116 may comprise any combination of devices that efficiently channel the flow of thermal energy between components 120-1 to 120-n (e.g., via the control of thermal transfer actuators 114-1 to 114-n) without substantially incurring more than nominal loss of heat to the environment. For example, in some embodiments the enthalpy distribution sub-system 116 may at least in part comprise a thermal junction block, such as a manifold or similar structure, that the thermal transfer controller 112 may manipulate to alter the flow of coolant between the components 120-1 to 120-n. A thermal junction block thus gives robust control to direct coolant for thermal management purposes and may be structured to at least in part avoid convective heat losses, frictional losses, and other various forms of energy loss.

In some embodiments, the plurality of thermal transfer actuators (114-1 to 114-n) may be controlled by a thermal transfer controller 112 that receives one or more control signals 154 from the enthalpy management controller 150. The thermal transfer controller 112 may be an integrated component of the thermal transfer system 110. In some embodiments, the enthalpy management controller 150 may indicate, via the one or more control signals 154, which of the components 120-1 to 120-n should respectively give and/or receive thermal energy, and/or an indication of how much thermal energy they should respectively give and/or receive (e.g., with respect to joules). The thermal transfer controller 112 receiving the one or more control signals 154 may then generate control signals to the thermal transfer actuators 114-1 to 114-n to adjust to the configuration specified by the enthalpy management controller 150.

As previously discussed, the enthalpy management controller 150 can generate one or more control signals 154 for controlling the flow of heat between components 120-1 to 120-n based on adaptive component enthalpy models 152. As previously discussed, each adaptive component enthalpy model 152 comprises a mathematical model that computes an expected enthalpy of the physical component with which it is associated, given sensor data comprising one or more observable, or computable, physical parameters of, and/or interacting with, the physical component. As shown in FIG. 1, for each component 120-1 to 120-n, the thermal management system 100 comprises a corresponding set of one or more sensors (depicted as 130-1 to 130-n) that measure parameters of the component that may be used for computing current heat load information. Example parameters that may be measured by sensors 130-1 to 130-n include, but are not limited to, temperatures, pressures, process flow rates, airflow speeds, air mass flow rates, or other parameters depending on the type of component for which enthalpy is being determined or estimated. The measurements obtained from each set of sensors 130-1 to 130-n are provided as corresponding sets of sensor data (shown at 140-1 to 140-2) as inputs to the adaptive component enthalpy models 152 for computing the enthalpy state variables (e.g., representing the heat load and/or a rate of change of heat load) for individual components of the plurality of components 120-1 to 120-n.

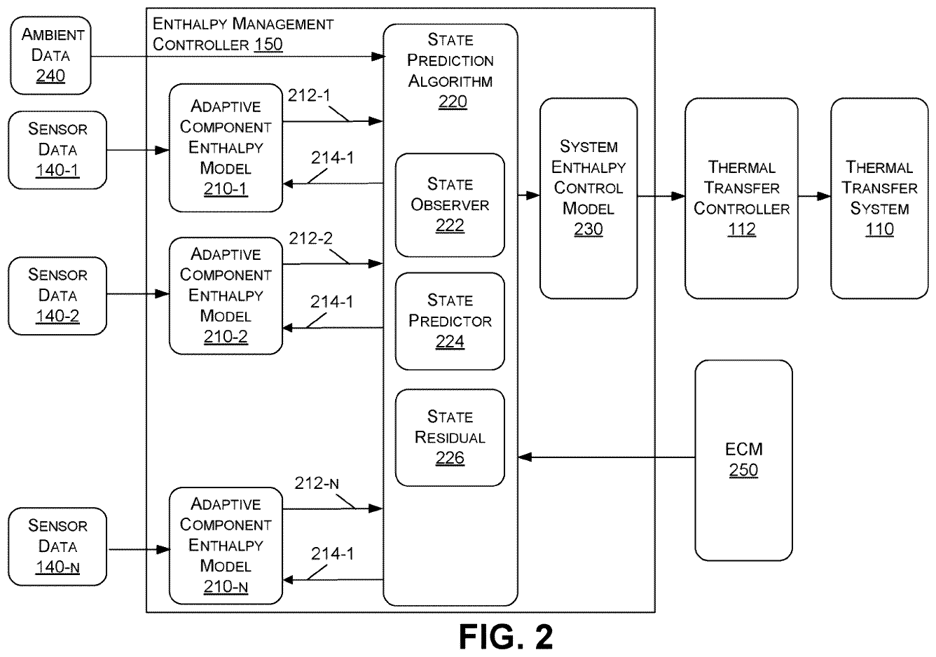

Referring now to FIG. 2, an enthalpy management controller, e.g., such as one similar to the enthalpy management controller 150 shown in FIG. 1, is illustrated, in accordance with an embodiment of the present disclosure. As shown in FIG. 2, the enthalpy management controller 150 includes a plurality of adaptive component enthalpy models (shown as 210-1 to 210-n) that each correspond to an individual component 120-1 to 120-n and model the enthalpy and/or change in enthalpy, of their corresponding component based at least on the sensor data 140-1 to 140-n generated by sensors 130-1 to 130-n. In some embodiments, the enthalpy management controller 150 may be implemented at least in part using a computing device 600 as illustrated and discussed with respect to FIG. 6, and/or a cloud computing platform 700 as illustrated and discussed with respect to FIG. 7. These platforms may be local or remote to a system the enthalpy management controller (e.g., a vehicle, ship, aircraft, or other equipment) operates to manage.

In some embodiments, the sensor data 140-1 to 140-n used by the adaptive component enthalpy models 210-1 to 210-n may include synthesized or estimated sensor data. For example, an adaptive component enthalpy model may be programmed to infer or compute an estimate of an internal core temperature of a component based on measurements of surface or casing temperatures (and/or other parameter measurements) and use that estimate as synthesized sensor data for computing enthalpy state variables (shown in FIG. 2 as model outputs 212-1 to 212-n).

The enthalpy management controller 150 may further include a state prediction algorithm 220 (e.g., a propagator-estimator) that includes a state observer 222 generated using the enthalpy model outputs 212-1 to 212-n. The state observer 222 may use the enthalpy model outputs 212-1 to 212-n (e.g., the heat load and/or a rate of change of heat load) computed by each of the adaptive component enthalpy models 210-1 to 210-n as real time state measurements representing an overall thermal state of the set of components monitored and managed by the thermal management system 100. Additional state variables used by the state observer 222 may represent ambient data 240, such as sensor-measured ambient environmental temperatures, humidity, vehicle speed, wind speed, and/or other ambient factors that may affect the heat loads of one or more of components 120-1 to 120-n.

In some embodiments, the state prediction algorithm 220 may comprise, or be implemented using, a Kalman filter, an extended Kalman filter (EKF), an unscented Kalman filter (UKF), an ensemble Kalman filter (EnKF), a constrained Kalman filter (CKF), and/or another form of linear or non-linear Kalman filter, state estimators, and/or a linear quadratic estimation (LQE) algorithm, for example. In other embodiments, the state prediction algorithm 220 may instead, or additionally, comprise a neural network algorithm, machine learning model, artificial intelligence, k-means clustering or other clustering algorithm, and/or other predictive technologies, for example. The state prediction algorithm 220 may further include a state predictor 224. The state predictor 224 may compute a statistically-based state estimate for a current set of estimated state variables (including uncertainties and/or measurement covariances) using a state estimate from a previous iteration (e.g., a previous timestep). These state variables of the state estimate produced by the state predictor 224 comprise representations of the heat load, or enthalpy, corresponding to each of the plurality of components 120-1 to 120-n. The state prediction algorithm 220 computes differences between the currently predicted state estimate and the current observed measurement information from the state observer 222, and those differences are used to further refine (e.g., update) the state estimate. This converges on increasingly accurate estimates of enthalpy by iteratively computing and updating the state estimate. That is, an updated state estimate for the present time-step is used as the “prior state estimate” for use in the next time-step.

As shown in FIG. 2, an enthalpy management controller 150 may further comprise a system enthalpy control model 230. The system enthalpy control model 230 may receive the state estimates of state variables from the state observer 222, and use the state estimates to generate the control signals 154 for adjusting the thermal transfer system 110. In some embodiments, the system enthalpy control model 230 may include, for example, machine learning models, crisp fuzzy logic (e.g., reliance on the ability of crisp functions, e.g., trapezoidal and/or triangular matrix, to calibrate fuzzy logic functions), and/or artificial intelligence models that are trained to recognize and/or infer future heat loads and/or heat flow patterns between components, and determine a configuration of the thermal transfer system 110 predicted to drive the heat load of each component to its respective operating enthalpy band. In some embodiments, the system enthalpy control model 230 may include rules-based policies, or other forms of logic, programed to evaluate the state variables and control the thermal transfer system 110 to drive the heat load of each component in a desired direction (e.g., into its respective operating enthalpy band, e.g., corresponding to an operating temperature range for example). For example, the system enthalpy control model 230 may be programed with logic that can predict changes to a component's heat load in response to transferring a given amount of thermal energy either to or from the component, and evaluate where the resulting heat load is in comparison to that component's operating enthalpy band. In some embodiments, based on the computations performed by the system enthalpy control model 230, the enthalpy management controller 150 generates one or more control signals 154 to control the thermal transfer system 110 to adjust the distribution of heat between the plurality of components 120-1 to 120-n to drive their respective heat loads based on their respective operating enthalpy bands. System enthalpy control model 230 may thus implement a predictive model based system which couples a component's thermal need to another components thermal availability. For example, the system enthalpy control model 230 may identify that excess friction generated heat from a vehicle's rotating axles can be transferred to a lubrication system that could use additional heat to keep a lubricant viscosity within a specified band. In some embodiments, the system enthalpy control model 230 may also execute historical trending based on observations of data from the sensors 130-1 to 130-n and/or outputs of the component enthalpy models 210-1 to 210-n to meet targets for cooling and/or heating of the components 120-1 to 120-n. For example, decision making by the system enthalpy control model 230 may also be based on systems efficiency as part of robust control, and in addition to efficiency, may also focus on trends of the actual data. In some embodiments, the system enthalpy control model 230 may determine the amount of thermal energy required from auxiliary components to meet the component thermal target in terms of cooling or heating performance when thermal energy transfer is not sufficiently available (e.g., wholly available) to/from an alternative one of the components 120-1 to 120-n. In some embodiments, the system enthalpy control model 230 may implement predictive thermal estimates based on upcoming road conditions along a predicted route. For example, the system enthalpy control model 230 may receive data from a vehicle navigation system, for example, indicating that there is an upcoming incline (e.g., a hill) and estimate thermal energy that will be generated in one or more of the components 120-1 to 120-n to climb the incline. Such an estimate may be used by the system enthalpy control model 230 to augment the state estimate data from the state observer 222, for example, to determine how to adjust the thermal transfer system 110 in anticipation of the incline to manage component enthalpy values. System enthalpy control model 230 may additionally or alternative receive data corresponding to weather events (e.g., upcoming rain, snow, temperature changes, and the like), traffic conditions (e.g., traffic jam where slow speeds cause particular components to heat differentially as compared to when traveling at high speed), etc., and may account for such data in terms of predictive thermal estimates.

By modeling component enthalpy rather than simply regulating based on temperature measurements, the enthalpy management controller 150 can more accurately account for each component's individual capacity to store thermal energy, receive thermal energy, donate thermal energy, and/or respond to changes in thermal energy flow and capacity, in order to share thermal energy between components 120-1 to 120-n.

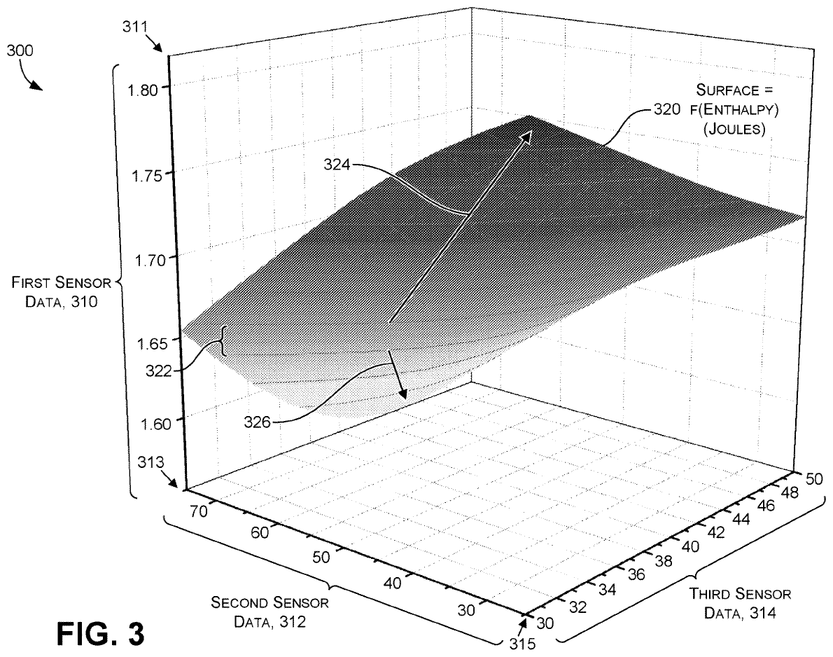

Referring now to FIG. 3, a graphical model representation 300 of a thermal state of a component (e.g., component 120-1 or others) as computed by its corresponding adaptive component enthalpy model (e.g., adaptive component enthalpy model 210-1) is shown, in accordance with an embodiment of the present disclosure. In this example, the sensor data inputs to the adaptive component enthalpy model reflected by the graphical model representation 300 include a first sensor data input 310 (plotted with respect to a first axis 311), a second sensor data input 312 (plotted with respect to a second axis 313), and a third sensor data input 314 (plotted with respect to a third axis 315). The surface 320 computed by the model based on the first, second and third sensor data inputs 310, 312, 314 describes the behavioral heat load response of the component to its present operational condition. For example, the sensor data may include data such as any of coolant temperature, coolant mass, flow rate, vehicle speed, air mass flow rate or other measurements depending on the component, while the surface 320 itself is a representation of enthalpy (e.g., joules of thermal energy). A given enthalpy point on the surface 320 for the set of coordinates corresponding to the intersection of the sensor data inputs to the model indicates the enthalpy state of the component at that point in time. Although the adaptive component enthalpy model depicted in FIG. 3 illustrates a three dimensional heat load response surface derived from sensor data as measured from three sensors, it should be understood that in other embodiments the adaptive component enthalpy model may compute an enthalpy state from sensor data comprising measurements from any number of sensors greater than or equal to one. For example, the surface 320 may comprise an n-dimensional (multi-dimensional) surface where n is based on the number of measurements represented by sensor data. Additionally, in some embodiments it is within the scope of this disclosure that values used as the axes of the enthalpy model need not necessarily solely be measured sensor values. For example, the values used as axes may, in some embodiments, be calculated values from multiple sensors or inputs. As a representative example, torque of an electric motor may not be directly measured on an e-axle, but may instead be calculated from a plurality of different sensing inputs in the powertrain inverters. Other similar examples are within the scope of this disclosure.

As shown in the graphical representation 300 in FIG. 3, an adaptive component enthalpy model may define an operating enthalpy band 322 on the surface 320, representing a desired heat load range that indicates the defined range of optimal heat loads for operating the component modeled by that adaptive component enthalpy model. In some embodiments, the operating enthalpy band 322 may be provided, for example by the component manufacturer, as a component specification. The operating enthalpy band 322 may be empirically derived for a component through experiment or experience. The enthalpy management controller 150 can determine when the thermal state of a component is outside of its desired operating enthalpy band 322 based on coordinates of the sensor data with respect to the surface 320. When enthalpy values are computed that indicate that the component is operating outside the operating enthalpy band 322, then that component is said to be operating with a sub-optimal heat load. For example, a model output indicating that the component is operating above the operating enthalpy band 322, such as shown at 324, can mean that the component is storing excess heat that may need to be shed. A model output indicating that the component is operating below the operating enthalpy band 322, such as shown at 326, can mean that the component may be operating with a deficiency in heat. The system enthalpy control model 230 can compare the enthalpy point determined by the model of one component with the enthalpy point determined by the model of one or more other components to determine where best, or more effectively, to redistribute excess heat. This can contribute to greater efficiency, performance, and less waste or disuse of excess heat that can otherwise be used to balance the enthalpy state of other components. The system enthalpy control model 230 may respond to a component outside of its operating enthalpy band 322 by controlling the thermal transfer system 110 to drive its heat load back into the operating enthalpy band 322. For example, the system enthalpy control model 230 may compute a vector along the surface 320 to bring a component back into the operating enthalpy band 322, and generate a control signal 154 to effectuate that vector by adding or removing heat from the component. For example, system enthalpy control model 230 may compute, e.g., based on the location and/or slope of a non-optimally overheated component's current enthalpy point on the surface 320 and the curve of the operating enthalpy band 322, a number of joules that would most quickly and/or efficiently return the component's enthalpy point to operating enthalpy band 322. Based on such computations, the system enthalpy control model 230 may generate control signals 154 to the thermal transfer controller 112 to effectuate the desired drop in enthalpy by transferring (via the thermal transfer system 110) the computed number of joules to one or more other components.

Similarly, the system enthalpy control model 230 may respond preemptively by controlling the thermal transfer system 110 to keep the component within its operating enthalpy band 322 when the output of the adaptive component enthalpy model indicates a trend and/or rate of change showing the component is likely to depart from its operating enthalpy band 322. That is, the system enthalpy control model 230 may proactively use enthalpy trending data to estimate how a component is responding to adjustments to the thermal transfer system 110 (and/or changes in system demands, such as when a vehicle changes speed or experiences changes in power demands) and control the thermal transfer system 110 to avoid components exiting their desired operating enthalpy band 322. In some embodiments, the state predication algorithm 220 (and/or other component of the enthalpy management controller 150) may receive data generated by an electronic control module (ECM) 250 and based on that data the system enthalpy control model 230 may adjust a configuration of the thermal transfer system 110 to account for expected changes in the enthalpy state of one or more of components 120-1 to 120-n as indicated by the data. For example, the system enthalpy control model 230 may receive data from an electronic control module 250 such as one or more of, but not limited to, an Engine Control Unit (ECU), a Transmission Control Unit (TCU), an Anti-lock Braking System (ABS), a Traction Control System (TCS), and/or a Body Control Module (BCM). Moreover, the system enthalpy control model 230 may preemptively account for heat that is self-generated by components 120-1 to 120-n based on demands on that component as indicated by the data from an electronic control module 250.

In some embodiments, the system enthalpy control model 230 may recognize that a component is within its operating enthalpy band 322, but has margin within that band to accept thermal energy from a component that is in excess of its operating enthalpy band 322. For example, vehicle batteries are a component that typically have substantial thermal mass, and therefore capacity to store excess thermal energy or heat generated by other components. That is, the materials and structure of the typical vehicle battery are of the nature that the battery can often accept many thousands of joules of heat, without causing more than a nominal increase in its temperature. As such, the system enthalpy control model 230 can control the thermal transfer system 110 to channel heat from a component with excess enthalpy to a receiving component such as the vehicle battery, with reduced concern of driving that receiving component out of its respective operating enthalpy band 322 relative to other possible receiving components (such as a cabin environment heater). For example, if a thermal component (e.g., inverter, drive axle, etc.) is running hot, rather than shedding that heat into the atmosphere, the system enthalpy control model 230 can control the thermal transfer system 110 to channel that excess heat to the vehicle battery (or other component with a thermal mass that can support storing heat). Conversely, another component may be operating at a heat deficit. In that case, the system enthalpy control model 230 can control the thermal transfer system 110 to channel heat from the vehicle battery to the component with a heat deficit, again with reduced concern of driving the battery out of its respective operating enthalpy band 322.

In some embodiments, a baseline adaptive component enthalpy model for individual components 120-1 to 120-n may be empirically determined. For example, enthalpy values corresponding to points on the surface 320 may be determined for a component for a plurality of different sets of sensor data inputs through testing of the component using test equipment. For example, test equipment may be used to subject a component under test to a set of scenarios that run the component through various operating conditions (e.g., temperatures, mass flow rates, rates of coolant, air convection, electric currents) while measuring heat rejection (indicative of heat load or enthalpy). The testing may include using the sensors 130-1 to 130-n associated with that component during testing to capture sensor data while subjecting the component to test conditions and measuring heat rejection, so that the measured heat loads can be correlated to captured sensor data to generate the surface 320 of an adaptive component enthalpy model.

In some embodiments, the enthalpy management controller 150 may determine when to incorporate, or transfer over to, the use of auxiliary thermal management components, such as traditional heaters, coolers, and the like, either in conjunction with, or instead of, the thermal transfer system. That is, the enthalpy management controller 150 may utilize weighting factors to provide the ability for a smooth transition between different control modes (e.g., enthalpy management versus traditional thermal management using auxiliary thermal management components). In some embodiments, the enthalpy management controller 150 may thus have the ability to use the benefit of using two different control approaches without necessarily maximizing either one of the control modes, while enabling a platform to meet targets for thermal operation.

Referring again to FIG. 2, in some embodiments, the state prediction algorithm 220 may use weighting factors (e.g., such as a weighted average) computed from measurement covariances to assign greater weight to state variables having less estimated uncertainty for predicting a next state estimate. The state prediction algorithm 220 may dynamically adjust these weighting factors to account for errors (e.g., deviations) in updated state estimates that can be considered expected deviations. Such deviations may be computed as a function of differences between state estimates and measurements from the state observer 222, and represented by state estimate residual 226. Such deviations may be random in nature and are often characterized as having predictable distributions (e.g., such as a normal (Gaussian) distribution). While the state prediction algorithm 220 may attempt to minimize random or expected deviation values represented by the state estimate residual 226, continued deviation trends in state estimates corresponding to one or more of the components may indicate a problem with model outputs computed for one or more of the adaptive component enthalpy models 210-1 to 210-n. For example, an adaptive component enthalpy model may be computing enthalpy state variables that no longer accurately reflect the actual enthalpy state of its associated component. There may have been a change affecting the component itself such that the enthalpy response of the component from receiving or shedding thermal energy through the thermal transfer system 110 is no longer accurately being modeled.

In some embodiments, the enthalpy management controller 150 monitors for occurrences where the enthalpy response of a component 120-1 to 120-n caused by the enthalpy management controller 150 adjusting the thermal transfer system 110 deviates from the response predicted by the state prediction algorithm 220 (e.g., in excess of a deviation threshold for that component). When the deviation associated with a component exceeds a deviation threshold, the enthalpy management controller 150 uses feedback from the state prediction algorithm 220 (shown as adjustments or feedback signals 214-1 to 214-n), which may be computed using the state estimate residual 226, to adjust the adaptive component enthalpy model to compensate for inaccuracies in enthalpy state variables computed by the model.

For example, in some embodiments, an adaptive component enthalpy model may use proportional-integral-derivative (PID) control algorithms, or other control law algorithm, to model component heat load characteristics. The enthalpy management controller 150 may use the feedback signals to adjust one or more coefficients of the algorithms used by the model to compute enthalpy state variables from sensor data. For example, the enthalpy management controller 150 may adjust coefficients of an adaptive component enthalpy model based on the feedback signals indicating that an enthalpy response for that component as predicted by the state prediction algorithm 220 was higher, lower, faster, slower, overdamped, underdamped, or otherwise outside of an anticipated numerical range, as compared to the observed response represented by the state observer 222.

In some embodiments, when cumulative adjustments to the adaptive component enthalpy model (e.g., as compared to a baseline) exceed one or more thresholds, the enthalpy management controller 150 may generate a warning signal, e.g., via an illuminated annunciator, a sound, a visual indicator, or the like. The warning may be used to alert an operator, for example, that the component needs to be scheduled for service. In some embodiments, adjustments to an adaptive component enthalpy model, and/or instances where thresholds are exceeded due to adjustments, may be reported to a maintenance server or other system.

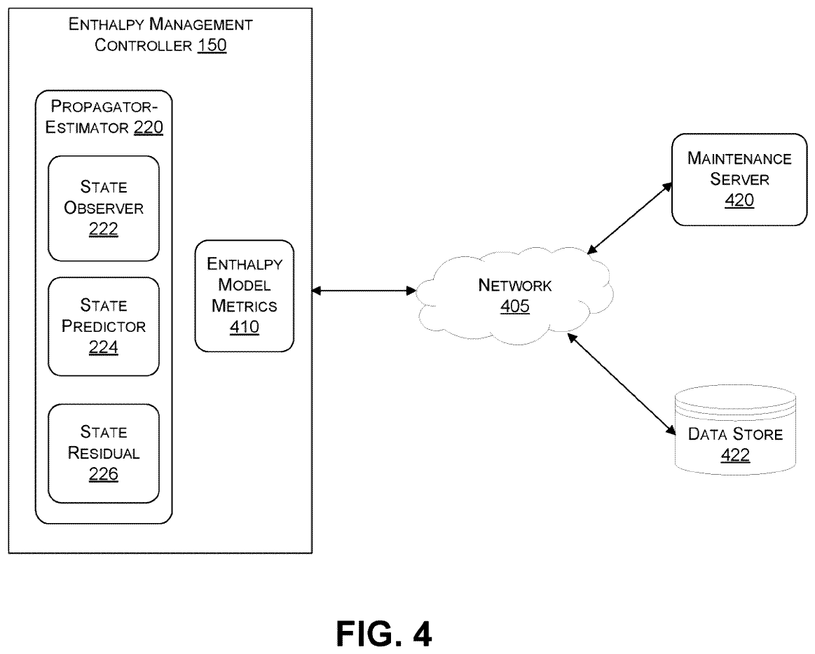

For example, the enthalpy management controller 150 may generate metrics representing adjustments made to the adaptive component models, shown in FIG. 4 as enthalpy model metrics 410. The enthalpy model metrics 410 may represent statistics regarding adjustments to an adaptive component enthalpy model to compensate for inaccuracies in enthalpy state variables computed by the model. In some embodiments, enthalpy model metrics 410 may be computed at least in part as a function of errors represented in the state residual 226. For example, in some embodiments, an adaptive component enthalpy model may be assigned a baseline efficiency coefficient (e.g., a coefficient of 1.0) when it is new and/or freshly serviced. Then, as the enthalpy management controller 150 makes adjustments to a particular model (e.g., such as adjustments to control law coefficients) the efficiency coefficient may be downgraded to reflect the accumulation of adjustments made to the model. For example, when the enthalpy management controller 150 makes adjustments to a model having an initial efficiency coefficient of 1.0, the efficiency coefficient may be reduced (e.g., to 0.98) proportionally to the degree of adjustment made to the model. When the efficiency coefficient is reduced to a threshold (e.g., 0.95), a warning, alert, or communication may be generated. Moreover, multiple threshold levels may be used to indicate potential severity levels of potential component degradation based on the cumulative degree of adjustments that have been made to an adaptive component enthalpy model. For example, a substantially reduced efficiency coefficient may indicate that a vehicle component, or other component dependent on that vehicle component, may incur degradation if not promptly serviced. Therefore when crossing a first efficiency coefficient threshold, it may be sufficient for the enthalpy management controller 150 to merely alert the driver that efficiency is reduced, but within a tolerable level. When a second efficiency coefficient threshold is crossed, the enthalpy management controller 150 may generate an alert to service the component at the next schedule service interval. When a third efficiency coefficient threshold is crossed, the enthalpy management controller 150 may generate an alert to seek immediate service to prevent irreversible component damage.

Also, as shown in FIG. 4, in some embodiments, the enthalpy management controller 150 may be coupled to one or both of a maintenance server 420 or to a data store 422, e.g., via a network 405. In some embodiments, the network 405 may include a wire network, a wireless network, or a combination thereof. The enthalpy management controller 150 may be coupled to the network 405 using a wireless network link via a wireless network interface, for example using radio(s) 624 as discussed below with respect to FIG. 6. Network 405 can include multiple networks, or a network of networks, but is shown in simple form so as not to obscure aspects of the present disclosure. By way of example, network 405 can include one or more wide area networks (WANs), one or more local area networks (LANs), one or more public networks such as the Internet, and/or one or more private networks. In some embodiments, the maintenance server 420 may receive from the enthalpy management controller 150 component efficiency information derived from the enthalpy model metrics 410. Based on the value of an efficiency coefficient or other statistic indicated by the enthalpy model metrics 410, the maintenance server 420 may generate one or more reports indicating that maintenance is due, and/or that service is needed or suggested for optimal performance, for one or more components managed by the thermal management system 100. In some embodiments, the enthalpy management controller 150 may periodically send component updates to the data store 422 based on the enthalpy model metrics 410, which may be used by the maintenance server 420 to generate the reports.

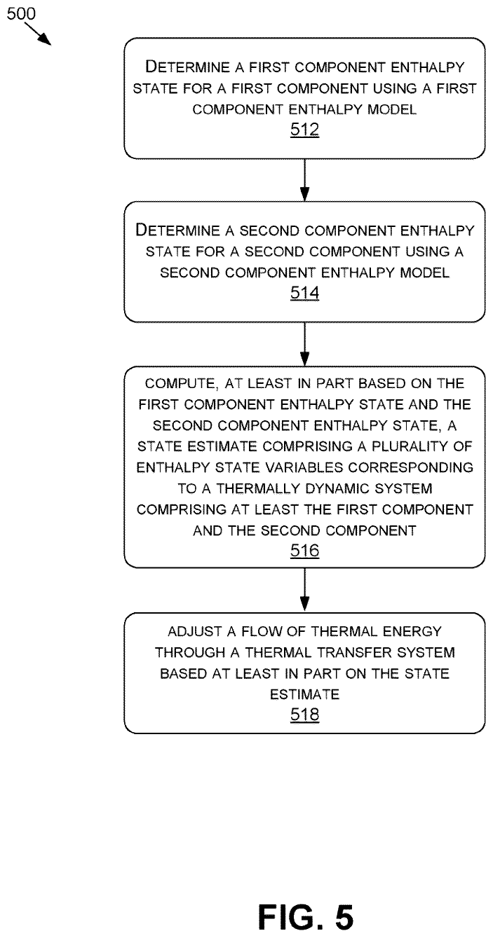

Referring now to FIG. 5, a flowchart illustrating a method 500 for enthalpy management is provided, in accordance with embodiments of the present disclosure. It should be understood that the features and elements described herein with respect to the method 500 of FIG. 5 can be used in conjunction with, in combination with, or substituted for elements of, any of the other embodiments discussed herein and vice versa. Further, it should be understood that the functions, structures, and other descriptions of elements for embodiments described in FIG. 5 can apply to like or similarly-named or described elements across any of the figures and/or embodiments described herein and vice versa. In some embodiments, elements of method 500 are implemented utilizing elements of the thermal management system 100 and/or enthalpy management controller 150 disclosed herein, or other processing device implementing the present disclosure.

The method 500 shown in FIG. 5 includes blocks 512-518, but is not limited to this selection of elements. The method 500 at block 512 includes determining a first component enthalpy state for a first component using a first component enthalpy model. The first component enthalpy model may compute the first component enthalpy state based on at least sensor data representing a parameter of the first component. The first component enthalpy state may comprise enthalpy state variables including one or both of an enthalpy value and a rate of change of enthalpy for the first component. In some embodiments, the first component enthalpy model models enthalpy of the first component as a multi-dimensional surface such as the one illustrated in FIG. 3.

The method 500 at block 514 includes determining a second component enthalpy state for a second component using a second component enthalpy model. The second component enthalpy model may compute the second component enthalpy state based on at least sensor data representing a parameter of the second component. The second component enthalpy state may comprise enthalpy state variables including one or both of an enthalpy value and a rate of change of enthalpy for the second component. In some embodiments, the second component enthalpy model models enthalpy of the second component as a multi-dimensional surface such as the one illustrated in FIG. 3.

In some embodiments, the first component and/or the second component may be any of the components 120-1 to 120-n illustrated in FIG. 1. In various embodiments, the first component and/or the second component may be at least one of: a vehicle battery; an electric motor; an internal combustion motor; a fuel cell; a breaking system component; an electrical circuit; a vehicle transmission system; a hydraulic system component; a pneumatic system component; a lubricating system component; a radiator; a heat exchanger; an axle; a valve; an actuator, a fluid supply line, or a cabin environmental regulation system, among other things.

The method 500 at block 516 includes computing, at least in part based on the first component enthalpy state and the second component enthalpy state, a state estimate comprising a plurality of enthalpy state variables corresponding to a thermally dynamic system comprising at least the first component and the second component. For example, the method 500 may be implemented in the context of a thermal management system for a vehicle, a robot, an industrial machine, and/or other mobile or stationary systems that are a thermally dynamic system (e.g., that has thermally active components). As the term is used herein, a thermally dynamic system is a system comprising elements having thermal states, such as enthalpy states that vary over time. In some embodiments, the method may include iteratively computing the state estimate using a state prediction algorithm that includes a state observer and a state predictor, such as that described above with respect to FIG. 2. The state observer may input the first component enthalpy state and the second component enthalpy state as state measurements, and the state predictor computes the state estimate for a first iteration of the state prediction algorithm based on the state observer and a prior state estimate from a prior iteration of the state prediction algorithm. In some embodiments, the state prediction algorithm comprises a propagator-estimator that generates a real time state observer using the outputs of the plurality of adaptive component enthalpy models for the plurality of components. Using a state predictor, for a given time-step the propagator-estimator may predict statistically based estimates corresponding to a current set of estimated enthalpy state variables (referred to as the state estimate), with their uncertainties, using a state estimate from the previous time-step. These enthalpy state variables represent the actual enthalpy values and/or rate of change in enthalpy corresponding to each of the plurality of components.

The method 500 may include monitoring for occurrences where the enthalpy response of a component caused by adjusting the thermal transfer system deviates from the response predicted, for example by the state prediction algorithm (e.g., in excess of a deviation threshold for that component). When the deviation associated with a component exceeds the deviation threshold, the adaptive component enthalpy model may be adjusted to compensate for inaccuracies in enthalpy state variables computed by the model.

In some embodiments, the method may include generating metrics representing adjustments made to the adaptive component models, such as the enthalpy model metrics 410 shown in FIG. 4. The enthalpy model metrics 410 may represent statistics regarding adjustments to an adaptive component enthalpy model to compensate for inaccuracies in enthalpy state variables computed by the model.

The method 500 at block 518 includes adjusting a flow of thermal energy through a thermal transfer system (such as the thermal transfer system 110 shown in FIG. 1, for example) based at least in part on the state estimate. In some embodiments, an enthalpy management controller generates the one or more control signals for controlling the flow of heat between components based on the state estimate, which in turn may be computed using the outputs of the adaptive component enthalpy models. Heat transfer between an enthalpy distribution sub-system (of the thermal transfer system) and the plurality of components may be bi-directionally controlled using one or more thermal transfer actuators. The thermal transfer actuators may be controlled by a thermal transfer controller that responds to one or more control signals from the enthalpy management controller. That is, the thermal transfer controller receiving the one or more control signals may generate control signals to the thermal transfer actuators to adjust the configuration specified by the enthalpy management controller, thus adjusting a flow of thermal energy through a thermal transfer system based at least in part on the state estimate. This thermal transfer can be accomplished through transfer of fluid through a thermal management assembly, e.g., one that includes one or more fluid pathways, one or more heat-exchangers, one or more radiators, one or more valves, couplings, and/or junctions, one or more actuators and/or control components, and/or other components that facilitate transfer of energy through a fluid pathway and to an internal component or to an external environment.

As an example use case, during colder temperatures, batteries of electric vehicle are less efficient, do not charge as fast, and may be more affected by electric demands from components like heating, regenerative braking or seat warming, without the benefits of an internal combustion engine which produces heat and drives an alternator to produce electric power. The enthalpy management controller 150 may determine that the vehicle battery, as a component, has an enthalpy state below its operating enthalpy band (e.g., it is not storing enough heat). The system enthalpy control model 230 can make the determination that the vehicle electric drive component is producing heat in a surplus at e.g., 5500 joules per second, and can share that surplus heat with the vehicle battery without deviating from its own operating enthalpy band. Moreover, the system enthalpy control model 230 may determine how much heat the vehicle battery needs from the vehicle electric drive to achieve an enthalpy state in its operating enthalpy band by further factoring both the amount of heat the battery will self-generate from supplying current to vehicle electric loads, and heat it is losing to the environment.

As another example use case, increases in the enthalpy state of an axle heating rate (as determined by the axle's adaptive component enthalpy model) may indicate that cooling of the axle is going to be needed soon. The enthalpy management controller may query or poll the adaptive component enthalpy models of other components to determine which component has capacity to take additional heat while remaining in its operating enthalpy band. The enthalpy management controller may determine that the vehicle batteries are already shedding heat to the radiator, which, based on its adaptive component enthalpy model, cannot take any additional heat due to ambient temperature conditions. The enthalpy management controller may determine to reconfigure the thermal transfer system to re-channel heat flow from the battery to another component with a corresponding capacity to accept the battery heat, and channel heat flow from the axle to the radiator to shed to the environment. An example system architecture that may be relied upon in such an example is disclosed in co-pending application GB2109718.3 “Thermal system with integrated valve device for an electric vehicle”, the contents of which is incorporated by reference herein in its entirety.

With regard to FIG. 6, one exemplary operating environment for implementing aspects of the technology described herein is shown and designated generally as computing device 600. For example, in some embodiments, one or more aspects of the thermal management system 100 can be implemented using computing device 600. Computing device 600 is just one example of a suitable computing environment and is not intended to suggest any limitation as to the scope of use or functionality of the technology described herein. Neither should the computing device 600 be interpreted as having any dependency or requirement relating to any one or combination of components illustrated.

The technology described herein can be described in the general context of computer code or machine-usable instructions, including computer-executable instructions such as program components, being executed by a computer or other machine, such as a personal data assistant or other handheld device. Generally, program components, including routines, programs, objects, components, data structures, and the like, refer to code that performs particular tasks or implements particular abstract data types. Aspects of the technology described herein can be practiced in a variety of system configurations, including vehicles, industrial machinery, robots, consumer electronics, general-purpose computers, and specialty computing devices. Aspects of the technology described herein can also be practiced in distributed computing environments where tasks are performed by remote-processing devices that are linked through a communications network. For example, the computing device 600 may comprise a computing device integrated within a vehicle, industrial machinery, robot, and/or other mobile or stationary systems having thermally active components.

With continued reference to FIG. 6, computing device 600 includes a bus 610 that directly or indirectly couples the following devices: memory 612, one or more processors 614, one or more presentation components 616, input/output (I/O) ports 618, I/O components 620, an illustrative power supply 622, and a radio(s) 624. In some embodiments, the bus 610 comprises a vehicle bus that interconnect components inside a vehicle.

Bus 610 represents one or more busses (such as an address bus, data bus, or combination thereof). Although the various blocks of FIG. 6 are shown with lines for the sake of clarity, it should be understood that one or more of the functions of the components can be distributed between components. For example, a presentation component 616 such as a display device can also be considered an I/O component 620. The diagram of FIG. 6 is merely illustrative of an exemplary computing device that can be used in connection with one or more aspects of the technology described herein. Distinction is not made between such categories as “workstation,” “server,” “laptop,” “tablet,” “smart phone” or “handheld device,” as all are contemplated within the scope of FIG. 6 and refer to “computer” or “computing device.”

In some embodiments, an enthalpy management controller and/or a thermal transfer controller, as described in any of the examples of this disclosure may be implemented at least in part using code executed by the one or more processors(s) 614. The state variables and/or other data generated by a state prediction algorithm may be stored at least in part by memory 612. In some embodiments, the one or more processors(s) 614 may include one or more central processing units (CPUs) 630 and/or one or more graphics processing units (GPUs) 632. In some embodiments, one or more of the adaptive component enthalpy modes and/or the system enthalpy control model may be implemented at least in part using a neural network inference engine executed on the one or more processors(s) 614.

Computing device 600 typically includes a variety of computer-readable media. Computer-readable media can be any available media that can be accessed by computing device 600 and includes both volatile and nonvolatile media, removable and non-removable media. By way of example, and not limitation, computer-readable media may comprise computer storage media and communication media. Computer storage media includes both volatile and nonvolatile, removable and non-removable media implemented in any method or technology for storage of information such as computer-readable instructions, data structures, program modules or other data.

Computer storage media includes non-transient RAM, ROM, EEPROM, flash memory or other memory technology, CD-ROM, digital versatile disks (DVD) or other optical disk storage, magnetic cassettes, magnetic tape, magnetic disk storage or other magnetic storage devices. Computer storage media and computer-readable media do not comprise a propagated data signal or signals per se.

Communication media typically embodies computer-readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of any of the above should also be included within the scope of computer-readable media.

Memory 612 includes computer-storage media in the form of volatile and/or nonvolatile memory. Memory 612 may be removable, non-removable, or a combination thereof. Exemplary memory includes solid-state memory, hard drives, optical-disc drives, etc. Memory 612 may include any type of tangible medium that is capable of storing information, such as a database. A database may include any collection of records, data, and/or other information.

Computing device 600 includes one or more processors 614 that read data from various entities such as bus 610, memory 612 or I/O components 620. One or more presentation components 616 present data indications to a person or other device. For example, presentation components 616 may include an in-cabin annunciator or human machine interface (HMI) which may display alerts, warnings, or other information generated by the enthalpy management controller. Exemplary one or more presentation components 616 include a display device, speaker, printing component, vibrating component, etc. I/O ports 618 allow computing device 600 to be logically coupled to other devices including I/O components 620, some of which may be built in computing device 600. Illustrative I/O components 620 include a microphone, joystick, game pad, satellite dish, scanner, printer, wireless device, display device, a controller (such as a keyboard, and a mouse), a natural user interface (NUI) (such as touch interaction, pen (or stylus) gesture, and gaze detection), and the like.

Radio(s) 624 represents a radio that facilitates communication with a wireless telecommunications network. For example, radio(s) 624 may comprise a wireless network interface used to establish communications with a server 420, data store 422, or other network provided service via the network 405 (as shown in FIG. 4). Illustrative wireless telecommunications technologies include CDMA, GPRS, TDMA, GSM, and the like. Radio 624 might additionally or alternatively facilitate other types of wireless communications including Wi-Fi, WiMAX, LTE, and/or other VoIP communications. As can be appreciated, in various embodiments, radio(s) 624 can be configured to support multiple technologies and/or multiple radios can be utilized to support multiple technologies.

The computing device 600, in some embodiments, is equipped with sensors such as, but not limited to, temperature sensors, pressure sensors, airflow sensors, air mass sensors, process flow sensors, electrical current and/or voltage sensors, image sensors, cameras, depth cameras, such as stereoscopic camera systems, infrared camera systems, RGB camera systems, and combinations of these, which may be used for generating sensor data for input to the adaptive component enthalpy models discussed herein. Additionally, the computing device 600, in some embodiments, is equipped with accelerometers or gyroscopes that enable detection of motion. The output of the accelerometers or gyroscopes can be provided to the display of the computing device 600 to render immersive augmented reality or virtual reality.

FIG. 7 is a diagram illustrating a cloud based computing environment 700 for implementing one or more aspects of the enthalpy management system with respect to any of the embodiments discussed herein. Cloud based computing environment 700 comprises one or more controllers 710 that each comprises one or more processors and memory, each programmed to execute code to implement at least part of the enthalpy management controller 150 (as shown in FIG. 1). In one embodiment, the one or more controllers 710 comprise server components of a data center. The controllers 710 may be configured to establish a cloud based computing platform executing aspects of the enthalpy management controller 150. For example, in some embodiments, one or more operations of the adaptive component enthalpy models, state prediction algorithm, and/or system enthalpy control model are virtualized network services running on a cluster of worker nodes 720 established on the controllers 710. For example, the cluster of worker nodes 720 can include one or more pods 722 (such as Kubernetes (K8s) pods) orchestrated onto the worker nodes 720 to realize one or more containerized applications 724 to implement the adaptive component enthalpy models, state prediction algorithm, and/or system enthalpy control model. In some embodiments, the thermal transfer controller 112 can be coupled to the controllers 710 by network 705 (for example, a public network such as the Internet, a proprietary network, or a combination thereof). In some embodiments, sensor data (140-1 to 140-n) may be provided to the controllers 710 by network 705. The enthalpy management controller 150 may be at least partially implemented by the containerized applications 724. In some embodiments the cluster of worker nodes 720 includes one or more one or more data store persistent volumes 730 that implement the data store 422.

### Example Clauses

Clause 1: A system comprising: one or more processors coupled to a memory, the one or more processors to perform operations comprising: determining a first component enthalpy state for a first component using a first component enthalpy model; determining a second component enthalpy state for a second component using a second component enthalpy model; computing, at least in part based on the first component enthalpy state and the second component enthalpy state, a state estimate comprising a plurality of enthalpy state variables corresponding to a thermally dynamic system comprising at least the first component and the second component; and adjusting a flow of thermal energy through a thermal transfer system based at least in part on the state estimate.

Clause 2: The system of clause 1, the operations further comprising: computing, using the first component enthalpy model, the first component enthalpy state based at least on sensor data representing a parameter of the first component; and computing, using the second component enthalpy model, the second component enthalpy state based at least on sensor data representing a parameter of the second component.

Clause 3: The system of any of clauses 1-2, wherein the first component enthalpy state comprises enthalpy state variables that include one or both of an enthalpy value, and a rate of change of enthalpy, for the first component, and wherein the second component enthalpy state comprises enthalpy state variables that include one or both of an enthalpy value, and a rate of change of enthalpy for the second component.

Clause 4: The system of clause 3 where the enthalpy state variables further include a quantification of deviations between the enthalpy of the first component and a desired thermal specification for that first component.

Clause 5: The system of any of clauses 1-4, the operations further comprising: iteratively computing the state estimate using a state prediction algorithm that includes a state observer and a state predictor; wherein the state observer inputs the first component enthalpy state and the second component enthalpy state as state measurements; and wherein the state predictor computes the state estimate for a first iteration of the state prediction algorithm based on the state observer and a prior state estimate from a prior iteration of the state prediction algorithm.

Clause 6: The system of any of clauses 1-5, the operations further comprising: adjusting the first component enthalpy model based at least in part on a deviation between an enthalpy response of the first component computed from the first component enthalpy model and an enthalpy response of the first component predicted from the state estimate.

Clause 7: The system of any of clauses 1-6, the operations further comprising: computing one or more enthalpy model metrics based on adjusting the first component enthalpy model; and generating an output based on the one or more enthalpy model metrics reaching a threshold.

Clause 8: The system of any of clauses 1-7, the operations further comprising: generating one or more control signals for adjusting the thermal transfer system based at least in part on the state estimate.

Clause 9: The system of any of clauses 1-8, the operations further comprising determining, using a system enthalpy control model based on the state estimate, a configuration of the flow of thermal energy through the thermal transfer system; and adjusting the flow of thermal energy through the thermal transfer system based on the configuration.

Clause 10: The system of any of clauses 1-9, the operations further comprising: further adjusting the flow of thermal energy through the thermal transfer system based at least in part on data generated by an electronic control module representing a change in an enthalpy state of the system.

Clause 11: The system of any of clauses 1-10, wherein the system comprises at least one of: a system of a vehicle; a system of a robot; and a system of an industrial machine.

Clause 12: The system of any of clauses 1-11, wherein the first component comprises at least one of: a vehicle battery; an electric motor; an internal combustion motor; a fuel cell; a breaking system component; an electrical circuit; a vehicle transmission system; a hydraulic system component; a pneumatic system component; a lubricating system component; a radiator; a heat exchanger; a valve; an actuator; a fluid supply lines, or a cabin environmental regulation system.

Clause 13: A system for enthalpy management, the system comprising: a plurality of sensors that generate sensor data representing one or more parameters of a plurality of components; an enthalpy distribution sub-system, wherein the enthalpy distribution sub-system distributes heat between the plurality of components based on a control signal; one or more processors coupled to a memory, the one or more processors to perform operations of an enthalpy management controller, the operations comprising: determining, based on the sensor data, a first component enthalpy state for a first component of the plurality of components using a first component enthalpy model; determining, based on the sensor data, a second component enthalpy state for a second component of the plurality of components using a second component enthalpy model; computing, at least in part based on the first component enthalpy state and the second component enthalpy state, a state estimate comprising a plurality of enthalpy state variables corresponding to a thermally dynamic system comprising at least the first component and the second component; and sending the control signal to adjust a flow of thermal energy through the thermal transfer system based at least in part on the state estimate.

Clause 14: The system of clause 13, wherein the first component enthalpy model models enthalpy of the first component as a first multi-dimensional surface; and wherein the second component enthalpy model models enthalpy of the second component as a second multi-dimensional surface.

Clause 15: The system of any of clauses 13-14, wherein the first component enthalpy state comprises enthalpy state variables that include an enthalpy value and/or a rate of change of enthalpy for the first component, and wherein the second component enthalpy state comprises enthalpy state variables that include an enthalpy value and/or a rate of change of enthalpy for the second component.

Clause 16: The system of any of examples 13-15, the operations further comprising: adjusting the flow of thermal energy through the thermal transfer system to drive the first component enthalpy state towards an operating enthalpy band defined based on the first component enthalpy model.

Clause 17: The system of any of clauses 13-16, the operations further comprising: adjusting the first component enthalpy model based at least in part on a deviation between an enthalpy response of the first component computed from the first component enthalpy model and an enthalpy response of the first component predicted by the enthalpy management controller from the state estimate.

Clause 18: A method for enthalpy management, the method comprising: determining a first component enthalpy state for a first component using a first component enthalpy model; determining a second component enthalpy state for a second component using a second component enthalpy model; computing, at least in part based on the first component enthalpy state and the second component enthalpy state, a state estimate comprising a plurality of enthalpy state variables corresponding to a thermally dynamic system comprising at least the first component and the second component; and adjusting a flow of thermal energy through a thermal transfer system based at least in part on the state estimate.

Clause 19: The method of clause 18, wherein the first component enthalpy state comprises enthalpy state variables including an enthalpy value and/or a rate of change of enthalpy for the first component, and wherein the second component enthalpy state comprises enthalpy state variables including an enthalpy value and/or a rate of change of enthalpy for the second component.

Clause 20: The method of any of clauses 18-19, further comprising: computing, with the first component enthalpy model, the first component enthalpy state based at least on sensor data representing a parameter of the first component; and computing, with the second component enthalpy model, the second component enthalpy state based at least on sensor data representing a parameter of the second component.

Clause 21: The method of any of clauses 18-20, further comprising one or both of: adjusting the first component enthalpy model based at least in part on a first deviation between an enthalpy response of the first component computed from the first component enthalpy model and an enthalpy response of the first component predicted from the state estimate; and adjusting the second component enthalpy model based at least in part on a second deviation between an enthalpy response of the second component computed from the second component enthalpy model and an enthalpy response of the second component predicted from the state estimate.

Clause 22: A method comprising: detecting a temperature and/or enthalpy of each of a plurality of different components of a system using a plurality of sensors; initiating a transfer of thermal energy from a first component of the plurality of components to a second component of the plurality of components based on the detected temperature and/or enthalpy of the plurality of different components.

Clause 23: The method of clause 22, wherein the transfer of thermal energy is based on a capacity of the first component to transfer thermal energy and remain within a first enthalpy band associated with the first component, and/or based on an amount of thermal energy needed by the second component to reach a second enthalpy band associated with the second component.

Clause 24: The method of clause 22 or 23, wherein the system is associated with a vehicle, ship, train, aircraft, power-generation equipment or a power plant, a robot, or an industrial machine or industrial equipment.

Clause 25: A method of manufacturing a system according to any of clauses 21-23.

Clause 26: Clauses 1-25 in any combination.

Clause 27: Clauses 1-25 in any combination wherein adjusting a flow of thermal energy through the thermal transfer system comprises controlling at least one actuator.

In various alternative embodiments, system and/or device elements, method steps, or example implementations described throughout this disclosure can be implemented at least in part using one or more computer systems, field programmable gate arrays (FPGAs), application specific integrated circuits (ASICs) or similar devices comprising a processor coupled to a memory and executing code to realize that elements, processes, or examples, said code stored on a non-transient hardware data storage device. Therefore, other embodiments of the present disclosure can include elements comprising program instructions resident on computer readable media which when implemented by such computer systems, enable them to implement the embodiments described herein. As used herein, the terms “computer readable media” and “computer storage media” refer to tangible memory storage devices having non-transient physical forms and include both volatile and nonvolatile, removable and non-removable media. Such non-transient physical forms can include computer memory devices, such as but not limited to: punch cards, magnetic disk or tape, or other magnetic storage devices, any optical data storage system, flash read only memory (ROM), non-volatile ROM, programmable ROM (PROM), erasable-programmable ROM (E-PROM), Electrically erasable programmable ROM (EEPROM), random access memory (RAM), CD-ROM, digital versatile disks (DVD), or any other form of permanent, semi-permanent, or temporary memory storage system of device having a physical, tangible form. By way of example, and not limitation, computer-readable media can comprise computer storage media and communication media. Computer storage media and computer readable media do not comprise a propagated data signal. Program instructions include, but are not limited to, computer executable instructions executed by computer system processors and hardware description languages such as Very High Speed Integrated Circuit (VHSIC) Hardware Description Language (VHDL).

Many different arrangements of the various components depicted, as well as components not shown, are possible without departing from the scope of the claims below. Embodiments in this disclosure are described with the intent to be illustrative rather than restrictive. Alternative embodiments will become apparent to readers of this disclosure after and because of reading it. Alternative means of implementing the aforementioned can be completed without departing from the scope of the claims below. Certain features and sub-combinations are of utility and can be employed without reference to other features and sub-combinations and are contemplated within the scope of the claims.

1. A system for enthalpy management, the system comprising:
a plurality of sensors that generate sensor data representing one or more parameters of a plurality of components;
a thermal transfer system comprising an enthalpy distribution sub-system, wherein the enthalpy distribution sub-system distributes heat between the plurality of components based on at least one control signal;
one or more processors coupled to a memory, the one or more processors to perform operations of an enthalpy management controller, the operations comprising:
determining, based on the sensor data, a first component enthalpy state for a first component of the plurality of components using a first component enthalpy model;
determining, based on the sensor data, a second component enthalpy state for a second component of the plurality of components using a second component enthalpy model;
computing, at least in part based on the first component enthalpy state and the second component enthalpy state, a state estimate comprising a plurality of enthalpy state variables corresponding to a thermally dynamic system comprising at least the first component and the second component; and
sending the at least one control signal to adjust a flow of thermal energy through the thermal transfer system based at least in part on the state estimate.

2. The system of claim 1, wherein the first component enthalpy model models enthalpy of the first component as a first multi-dimensional surface; and wherein the second component enthalpy model models enthalpy of the second component as a second multi-dimensional surface.

3. The system of claim 1, wherein the first component enthalpy state comprises enthalpy state variables that include one or both of an enthalpy value, and a rate of change of enthalpy, for the first component, and wherein the second component enthalpy state comprises enthalpy state variables that include one or both of an enthalpy value, and a rate of change of enthalpy, for the second component.

4. The system of claim 1, the operations further comprising:
adjusting the flow of thermal energy through the thermal transfer system to drive the first component enthalpy state towards an operating enthalpy band defined based on the first component enthalpy model.

5. The system of claim 1, the operations further comprising:
adjusting the first component enthalpy model based at least in part on a deviation between an enthalpy response of the first component computed from the first component enthalpy model and an enthalpy response of the first component predicted by the enthalpy management controller from the state estimate.

6. A method for enthalpy management using the system of claim 1, the method comprising:
determining the first component enthalpy state for the first component using the first component enthalpy model;
determining the second component enthalpy state for the second component using the second component enthalpy model;
computing, at least in part based on the first component enthalpy state and the second component enthalpy state, the state estimate comprising the plurality of enthalpy state variables corresponding to the thermally dynamic system comprising at least the first component and the second component; and
adjusting the flow of thermal energy through the thermal transfer system based at least in part on the state estimate, wherein the thermal transfer system is in thermal communication with the first component and the second component.

7. The method of claim 6, further comprising:
computing, using the first component enthalpy model, the first component enthalpy state based at least on sensor data representing a parameter of the first component; and
computing, using the second component enthalpy model, the second component enthalpy state based at least on sensor data representing a parameter of the second component.

8. The method of claim 6, further comprising at least one of:
adjusting the first component enthalpy model based at least in part on a first deviation between an enthalpy response of the first component computed from the first component enthalpy model and an enthalpy response of the first component predicted from the state estimate; and
adjusting the second component enthalpy model based at least in part on a second deviation between an enthalpy response of the second component computed from the second component enthalpy model and an enthalpy response of the second component predicted from the state estimate.

9. A system comprising a vehicle, a robot, or an industrial machine, further comprising the system of claim 1.

10. A machine-readable medium carrying machine-executable instructions, which when executed by one or more processors of a machine, causes the machine to carry out the method of claim 6.

11. A system in accordance with claim 1, wherein the first component or the second component comprises at least one of:
a vehicle battery;
an electric motor;
an internal combustion motor;
a fuel cell;
a braking system component;
an electrical circuit;
a vehicle transmission system;
a hydraulic system component;
a pneumatic system component;
a lubricating system component;
a radiator;
a heat exchanger;
a valve;
an actuator;
a fluid supply line; or
a cabin environmental regulation system.

12. A method for enthalpy management, the method comprising:
determining a first component enthalpy state for a first component using a first component enthalpy model;
determining a second component enthalpy state for a second component using a second component enthalpy model;
computing, at least in part based on the first component enthalpy state and the second component enthalpy state, a state estimate comprising a plurality of enthalpy state variables corresponding to a thermally dynamic system comprising at least the first component and the second component; and
adjusting a flow of thermal energy through a thermal transfer system based at least in part on the state estimate, wherein the thermal transfer system is in thermal communication with the first component and the second component.

13. The method of claim 12, wherein the first component enthalpy state comprises enthalpy state variables including one or both of an enthalpy value, and a rate of change of enthalpy, for the first component, and wherein the second component enthalpy state comprises enthalpy state variables including one or both of an enthalpy value, and a rate of change of enthalpy, for the second component.

14. The method claim 12, further comprising:
computing, using the first component enthalpy model, the first component enthalpy state based at least on sensor data (140-1) representing a parameter of the first component; and
computing, using the second component enthalpy model, the second component enthalpy state based at least on sensor data representing a parameter of the second component.

15. The method of claim 12, further comprising at least one of:
adjusting the first component enthalpy model based at least in part on a first deviation between an enthalpy response of the first component computed from the first component enthalpy model and an enthalpy response of the first component predicted from the state estimate; and
adjusting the second component enthalpy model based at least in part on a second deviation between an enthalpy response of the second component computed from the second component enthalpy model and an enthalpy response of the second component predicted from the state estimate.

16. A machine-readable medium carrying machine-executable instructions, which when executed by one or more processors of a machine, causes the machine to carry out the method of claim 12.

17. A system for enthalpy management, the system comprising:
one or more processors coupled to a memory, the one or more processors (614) configured to perform operations comprising:
determining a first component enthalpy state for a first component using a first component enthalpy model;
determining a second component enthalpy state for a second component using a second component enthalpy model;
computing, at least in part based on the first component enthalpy state and the second component enthalpy state, a state estimate comprising a plurality of enthalpy state variables corresponding to a thermally dynamic system comprising at least the first component and the second component; and
adjusting a flow of thermal energy through a thermal transfer system based at least in part on the state estimate.

18. The system of claim 17, the operations further comprising:
computing, using the first component enthalpy model, the first component enthalpy state based at least on sensor data representing a parameter of the first component; and
computing, using the second component enthalpy model, the second component enthalpy state based at least on sensor data representing a parameter of the second component.

19. The system of claim 17, wherein the first component enthalpy state comprises enthalpy state variables that include one or both of an enthalpy value, and a rate of change of enthalpy, for the first component, and wherein the second component enthalpy state comprises enthalpy state variables that include one or both of an enthalpy value, and a rate of change of enthalpy for the second component.

20. The system of claim 17, the operations further comprising:
iteratively computing the state estimate using a state prediction algorithm that includes a state observer and a state predictor;
wherein the state observer inputs the first component enthalpy state and the second component enthalpy state as state measurements; and
wherein the state predictor computes the state estimate for a first iteration of the state prediction algorithm based on the state observer and a prior state estimate from a prior iteration of the state prediction algorithm.

21. The system of claim 17, the operations further comprising:
adjusting the first component enthalpy model based at least in part on a deviation between an enthalpy response of the first component computed from the first component enthalpy model and an enthalpy response of the first component predicted from the state estimate.

22. The system of claim 17, the operations further comprising:
computing one or more enthalpy model metrics based on adjusting the first component enthalpy model; and
generating an output based on the one or more enthalpy model metrics reaching a threshold.

23. The system of claim 17, the operations further comprising:
generating one or more control signals for adjusting the thermal transfer system based at least in part on the state estimate.

24. The system of claim 17, the operations further comprising:
determining, using a system enthalpy control model based on the state estimate, a configuration of the flow of thermal energy through the thermal transfer system; and
adjusting the flow of thermal energy through the thermal transfer system based on the configuration.

25. The system of claim 17, the operations further comprising:
further adjusting the flow of thermal energy through the thermal transfer system based at least in part on data generated by an electronic control module representing a change in an enthalpy state of the system.

26. A system comprising a vehicle, a robot, or an industrial machine, further comprising the system of claim 17.

27. The system of claim 17, wherein the first component or the second component comprises at least one of:
a vehicle battery;
an electric motor;
an internal combustion motor;
a fuel cell;
a braking system component;
an electrical circuit;
a vehicle transmission system;
a hydraulic system component;
a pneumatic system component;
a lubricating system component;
a radiator;
a heat exchanger;
a valve;
an actuator;
a fluid supply line; or
a cabin environmental regulation system.

28. A method for enthalpy management using the system of claim 17, the method comprising:
determining the first component enthalpy state for the first component using the first component enthalpy model;
determining the second component enthalpy state for the second component using the second component enthalpy model;
computing, at least in part based on the first component enthalpy state and the second component enthalpy state, the state estimate comprising the plurality of enthalpy state variables corresponding to the thermally dynamic system comprising at least the first component and the second component; and
adjusting the flow of thermal energy through the thermal transfer system based at least in part on the state estimate, wherein the thermal transfer system is in thermal communication with the first component and the second component.

29. A machine-readable medium carrying machine-executable instructions, which when executed by one or more processors of a machine, causes the machine to carry out the method of claim 28.
